(19) United States
(12) Patent Application Publication
(10) Pub. No.: US 2026/0261116 A1
(43) Pub. Date: Sep. 3, 2026

(54) ACTIVE CLAMP CIRCUIT, SEMICONDUCTOR DEVICE, ELECTRONIC DEVICE, AND VEHICLE

(71) Applicant: ROHM CO., LTD., Kyoto-shi (JP)

(72) Inventors: Shojiro KATO, Kyoto-shi (JP); Kazuki OKUYAMA, Kyoto-shi (JP); Joita ADRIAN, Kyoto-shi (JP); Shuntaro TAKAHASHI, Kyoto-shi (JP); Toru TAKUMA, Kyoto-shi (JP)

(21) Appl. No.: 19/653,689

(22) Filed: Apr. 21, 2026

Related U.S. Application Data
(63) Continuation of application No. PCT/JP2024/037400, filed on Oct. 21, 2024.

(30) Foreign Application Priority Data
Oct. 25, 2023 (JP) 2023-183428

(51) Int. Cl. H02H 9/04; H03K 17/081

(52) U.S. Cl. CPC H02H 9/04; H03K 17/081

(57) ABSTRACT

An active clamp circuit includes a first transistor having its first main electrode connected to the control electrode of an output transistor, a first diode and a second diode serially connected with opposite polarities between the control electrode and the second main electrode of the first transistor, a second transistor having its first main electrode connected to the second main electrode of the first transistor and having its second main electrode connected to the first main electrode of the output transistor, a first resistor connected between the control electrode and the first main electrode of the second transistor, and a third diode connected between the control electrode and the second main electrode of the second transistor.

### CROSS REFERENCE TO RELATED APPLICATIONS

This application is a continuation under 35 U.S.C. § 120 of PCT/JP2024/037400, filed Oct. 21, 2024, which is incorporated herein by reference, and which claimed priority to Japanese Application No. 2023-183428, filed Oct. 25, 2023. The present application likewise claims priority under U.S.C. § 119 to Japanese Application No. 2023-183428, filed Oct. 25, 2023, the entire content of which is also incorporated herein by reference.

### TECHNICAL FIELD

The present disclosure relates to an active clamp circuit, a semiconductor device, an electronic device, and a vehicle.

### Background Art

The applicant of the present disclosure has devised many new technologies regarding a semiconductor device called an IPD (intelligent power device) or an SPS (smart power switch) (for example, see Patent Document 1).

### CITATION LIST

### Patent Literature

Patent Document 1: WO2017/187785

### BRIEF DESCRIPTION OF DRAWINGS

FIG. 1 is a diagram showing one configuration example of an electronic device incorporating a semiconductor device.

FIG. 2 is a diagram showing a semiconductor device of a first embodiment.

FIG. 3 is a diagram showing one example of active clamp operation.

FIG. 4 is a diagram showing the vertical structure of a transistor.

FIG. 5 is a diagram showing a semiconductor device of a second embodiment.

FIG. 6 is a diagram showing the vertical structure of a dummy transistor.

FIG. 7 is a diagram showing a semiconductor device of a third embodiment.

FIG. 8 is a diagram showing the exterior appearance of a vehicle.

### DESCRIPTION OF EMBODIMENTS

### Electronic Device

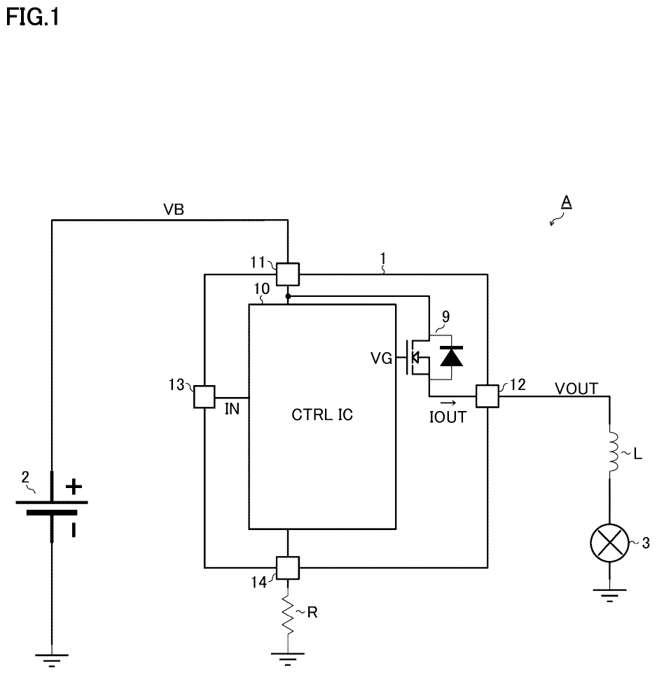

FIG. 1 is a diagram showing one configuration example of an electronic device incorporating a semiconductor device. The electronic device A of this configuration example includes a semiconductor device 1, a direct-current power source 2, and a load 3.

The semiconductor device 1 is a high-side switch IC (a kind of IPD) that electrically connects and disconnects between the direct-current power source 2 and the load 3. In terms of what is shown in the diagram, the semiconductor device 1 has integrated in it an output transistor 9 and a controller 10.

The semiconductor device 1 also includes a plurality of external electrodes for electrical connection with outside the device. In terms of what is shown in the diagram, the semiconductor device 1 includes an external electrode 11 (corresponding to a power source electrode), an external electrode 12 (corresponding to an output electrode), an external electrode 13 (corresponding to an input electrode), and an external electrode 14 (corresponding to a reference voltage electrode).

The output transistor 9 is one example of an insulated gate power transistor. The output transistor 9 functions as a high-side switch to electrically connect and disconnect between the external electrode 11 and the external electrode 12. Suitably usable as the output transistor 9 is, for example, an N-channel power MOSFET (metal-oxide-semiconductor field-effect-transistor).

Note that, in the present description, a MOSFET denotes a transistor having a gate structure composed of at least three layers, namely “a layer of a conductor or a semiconductor with a low resistance, such as polysilicon,” “an insulating layer,” and “a semiconductor layer of a P-type, an N-type, or an intrinsic type.” That is, the gate structure of a MOSFET is not limited to the three-layer structure of a metal, an oxide, and a semiconductor.

The controller 10 includes different kinds of functional circuits to accomplish various functions. For example, the different kinds of functional circuits include a circuit that generates a gate control signal VG to control the driving of the output transistor 9 based on an external electric signal (input signal IN). For example, basically, if the input signal IN is at high level, the controller 10 keeps the gate control signal VG at high level to keep the output transistor 9 on. On the other hand, basically, if the input signal IN is at low level, the controller 10 keeps the gate control signal VG at low level to keep the output transistor 9 off.

The external electrode 11 feeds a power source voltage VB to the drain of the output transistor 9 and to the circuits in the controller 10. The external electrode 12 is connected to the source of the output transistor 9 and feeds an output voltage VOUT and an output current IOUT to the load 3. Typically, a wire (harness) laid between the external electrode 12 and the load 3 is accompanied by an inductive component L (and a resistive component). In addition, to the external electrode 11, a device using a winding (coil), such as a solenoid, a motor, a transformer, or a relay, can be externally connected as an inductive load with an inductive component L. The external electrode 13 feeds an input voltage (input signal IN) for driving the controller 10. The external electrode 14 feeds a reference voltage (e.g., a ground voltage) to the controller 10. Typically, a resistive component R accompanies the path between the external electrode 14 and a ground terminal.

### First Embodiment

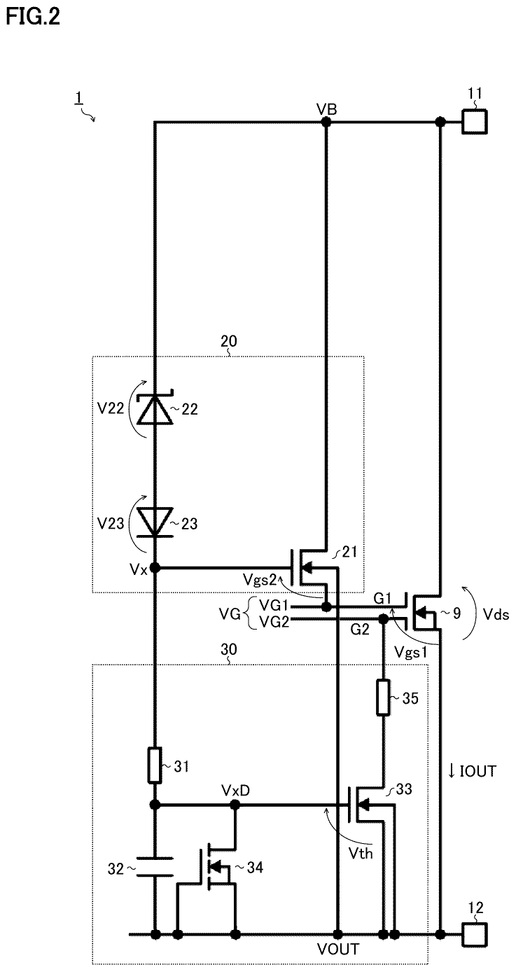

FIG. 2 is a diagram showing a semiconductor device 1 of a first embodiment (corresponding to a comparative example to be compared with a second and a third embodiment, which will be described later). As shown in the diagram, the semiconductor device 1 of this embodiment includes, in addition to the components described previously (in this diagram, only the output transistor 9 and the external electrodes 11 and 12 are shown), an active clamp circuit 20 and a gate disabling circuit 30.

The drain of the output transistor 9 is connected to the external electrode 11. T source and the back gate of the output transistor 9 are connected to the external electrode 12. Note that the semiconductor device 1 of this embodiment uses as the output transistor 9 a split-gate device having two gates G1 and G2. To the gates G1 and G2, gate control signals VG1 and VG2 are fed, respectively, as the gate control signal VG previously mentioned. With this configuration, it is possible to individually control a first and a second channel region of the output transistor 9.

The active clamp circuit 20 protects the output transistor 9 from a back electromotive force in an inductive component L (see FIG. 1) that can be externally connected to the external electrode 12. In terms of what is shown in the diagram, the active clamp circuit 20 includes a transistor 21, an m-stage (e.g., m=7) series diode 22, and an n-stage (e.g., n=3) series diode 23. The transistor 21 can be an N-channel MOSFET. The diode 22 can be a Zener diode. The diode 23 can be a polysilicon diode.

The drain of the transistor 21 is connected to the drain of the output transistor (hence to the external electrode 11). The source of the transistor 21 is connected to the gate G1 of the output transistor 9. The gate of the transistor 21 is connected to an application terminal for an internal node voltage Vx. The back gate of the transistor 21 is connected to the source and the back gate of the output transistor 9 (hence to the external electrode 12). Note that the internal node voltage Vx corresponds to an internal signal indicating whether the drain-source voltage Vds (=VB−VOUT) of the output transistor 9 is higher than a predetermined threshold voltage (=β) lower than the clamp voltage Vclp (=α).

The cathode of the diode 22 is connected to the drain of the transistor 21. The anode of the diode 22 is connected to the anode of the diode 23. The cathode of the diode 23 is connected to the application terminal for the internal node voltage Vx. As shown in this diagram, the diodes 22 and 23 are connected in series with opposite polarities (reverse-biased) between the gate and the drain of the transistor 21.

The gate disabling circuit 30 receives the internal node voltage Vx from the active clamp circuit 20 and has a function to short-circuit between the gate G2 and the source of the output transistor 9 when, after the input signal IN is turned from high level to low level, the active clamp circuit 20 clamps the output voltage VOUT. That is, in active clamp operation, the gate disabling circuit 30 makes G2 equal to VOUT to disable the gate G2 of the output transistor 9 so as to perform half-on control for the output transistor 9.

In terms of what is shown in the diagram, the gate disabling circuit 30 includes resistor 31, a capacitor 32, transistors 33 and 34, and a resistor 35. The transistors 33 and 34 can both be N-channel MOSFETs. In particular, the transistor 34 can be of a depletion type.

The first terminal of the resistor 31 is connected to the application terminal for the internal node voltage Vx. The second terminal of the resistor 31, the first terminal of the capacitor 32, the gate of the transistor 33, and the drain of the transistor 34 are all connected to an application terminal for a delayed internal node voltage VxD. The second terminal of the capacitor 32, the source and the back gate of the transistor 33, the gate, the source, and the back gate of the transistor 34 are all connected to the source and the back gate of the output transistor 9 (hence to the external electrode 12). The first terminal of the resistor 35 is connected to the gate G2 of the output transistor 9. The second terminal of the resistor 35 is connected to the drain of the transistor 33.

Of the components mentioned above, the resistor 31 and the capacitor 32 function as a delay circuit that generates the delayed internal node voltage VxD by delaying by a predetermined delay time td the internal node voltage Vx (in the diagram, the gate voltage of the transistor 21) of the active clamp circuit 20.

Note that, as the internal node voltage Vx, for example, as shown in the diagram, the gate voltage of the transistor 21 can be fed in. This, however, is not meant as any limitation on the internal node voltage Vx; for example, any anode voltage in the n-stage series diode 23 can be used as the internal node voltage Vx.

The transistor 33 is turned on and off according to the delayed internal node voltage VxD. When the transistor 33 is on, the path between the gate G2 and the source of the output transistor 9 is short-circuited. This state corresponds to a state where the gate G2 is disabled. On the other hand, when the transistor 33 is off, the path between the gate G2 and the source of the output transistor 9 is left open. This state corresponds to a state where the gate G2 is enabled.

That is, the gate disabling circuit 30 turns on and off the transistor 33 according to the delayed internal node voltage VxD to enable and disable the gate G2.

Note that, after the input signal IN falls to low level, when the output voltage VOUT of the external electrode 12 becomes negative, the active clamp circuit 20, by controlling the gate G1, forcibly turns on the first channel region of the output transistor 9 (into a state where it is not fully off). With this active clamp operation, the drain-source voltage Vds (=VB−VOUT) of the output transistor 9 can be limited to equal to or lower than the predetermined clamp voltage Vclp. On the other hand, in this active clamp operation, the gate G2 of the output transistor 9 is disabled.

In this way, the active clamp circuit 20 drives the gate G1 with the gate G2 of the output transistor 9 disabled to perform active clamp operation. Note that the gate G1 of the output transistor 9 can be understood to be a clamp gate involved in active clamp operation. On the other hand, the gate G2 of the output transistor 9 can be understood to be a non-clamp gate not involved in active clamp operation (the details will be given later).

Half-on control for the output transistor 9 in active clamp operation will be described below assuming that the gate-source voltage between the gate G1 and the source of the output transistor 9 is Vgs1, that the gate-source voltage of the transistor 21 is Vgs2, that the on threshold voltage of the transistor 33 is Vth, that the breakdown voltage of the diode 22 is V22 (=mVZ), and that the forward drop voltage of the diode 23 is V23 (=nVF).

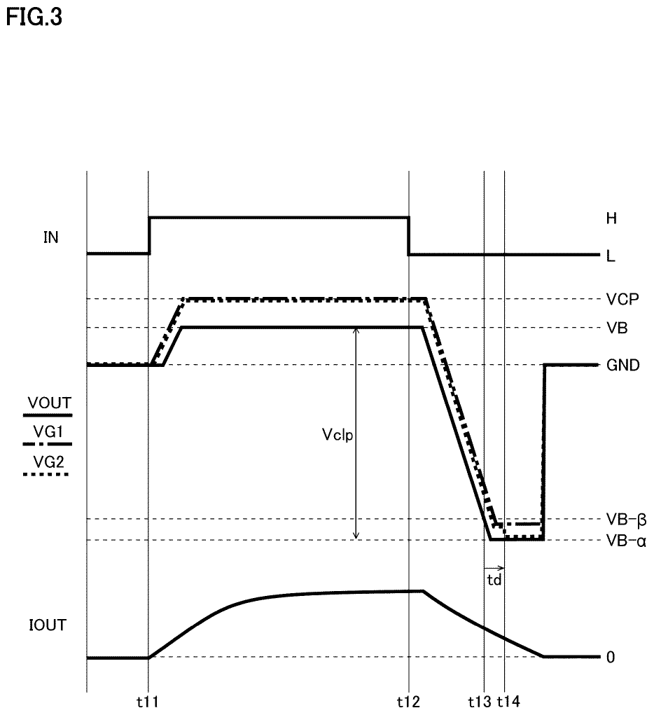

FIG. 3 illustrates one example of active clamp operation (in particular, how half-on control is performed for the output transistor 9 in active clamp operation in the semiconductor device 1). This diagram depicts, from top down, the input signal IN, the output voltage VOUT (solid line), the gate control signals VG1 (chain line) and VG2 (broken line), and the output current IOUT. Note that, in this diagram, it is assumed that an inductive component L is present between the external electrode 12 and the ground terminal.

When at time t11 the input signal IN rises to high level (corresponding to the logic level to turn on the output transistor 9), the gate control signals VG1 and VG2 rise to high level (≈VCP>VB). Thus, the first and second channel regions of the output transistor 9 both turn on. As a result, the output current IOUT starts to flow, so that the output voltage VOUT rises to around the power source voltage VB. This state corresponds to a fully-on state of the output transistor 9.

Then, when at time t12 the input signal IN falls to low level (corresponding to the logic level to turn off the output transistor 9), to turn off both the first and second channel regions of the output transistor 9, the gate control signals VG1 and VG2 fall to low level (≈VOUT).

In the meantime, the inductive component L connected to the external electrode 12 keeps passing the output current IOUT until it discharges the energy stored during the on period of the output transistor 9. As a result, the output voltage VOUT rapidly drops to a negative voltage lower than the ground voltage GND.

After that, when, during the period between times t13 and t14, the output voltage VOUT falls to a lower-limit voltage VB−α (e.g., VB−50 V) lower than the power source voltage VB by a predetermined value α (=V22+V23+Vgs2+Vgs1), the active clamp circuit 20 operates to turn on the first channel region of the output transistor 9 (into a state where it is not fully-off). This discharges the output current IOUT via the output transistor 9. Thus, the output voltage VOUT is limited to equal to or higher than the lower-limit voltage VB−α.

That is, the active clamp circuit 20 limits the output voltage VOUT with reference to the power source voltage VB to make the drain-source voltage Vds (=VB−VOUT) of the output transistor 9 equal to or lower than a predetermined clamp voltage Vclp (=α). This active clamp operation continues until the energy stored in the inductive component L is completely discharged and the output current IOUT no longer flows.

The description continues with focus on the gate G2 of the output transistor 9. After the input signal IN is turned from high level to low level, at time t13, the output voltage VOUT falls to a channel switch voltage VB−β (>VB−α) lower than the power source voltage VB by a predetermined value β (=V22+V23+Vgs2). In the meantime, the internal node voltage Vx becomes higher than the on-threshold voltage Vth of the transistor 33.

Thus, if the internal node voltage Vx is applied directly to the gate of the transistor 33, at time t13, the transistor 33 is turned on without delay, and the path between the gate G2 and the source of the output transistor 9 is short-circuited (G2=VOUT). That is, when the resistor 31 and the capacitor 32 are omitted, before the active clamp circuit 20 clamps the output voltage VOUT, the gate G2 is disabled. This state corresponds to a half-on state of the output transistor 9.

In this way, switching from a fully-on state to a half-on state reduces the usage rate of the channel in active clamp operation, as compared with that in non-active clamp operation. Thus, it is possible both to reduce an on-resistance in non-clamp operation and to improve the active clamping capacity in clamp operation.

Note that, in the semiconductor device 1 of this embodiment, as shown in the diagram, during the period from time t13 to time t14 when a predetermined delay time td elapses, switching from the fully-on state to the half-on state is suspended. That is, the timing when the gate G2 of the output transistor 9 is disabled is delayed by the delay time td.

With this delay time td, even if, for example, with the external electrode 12 (i.e., output electrode) ground-shorted via a wire harness, the output transistor 9 is turned off and the output current IOUT increases instantaneously, before the on-resistance of the output transistor 9 is raised, the high current can be absorbed (clamped). This helps suppress an overshoot in the output voltage VOUT.

Note that the energy stored in the inductive component L of the wire harness is not very high. Thus, the delay time td can be set to a duration enough to absorb (clamp) an instantaneous high current. In terms of what is shown in the diagram, the delay time td is set such that switching to the half-on state is performed promptly after the output voltage VOUT is clamped to the lower-limit voltage VB−α.

Providing the above delay time td may arouse concern about a drop in the active clamping capacity if there is no output short-circuit in the external electrode 12. However, the above delay time td is short enough relative to the active clamping time (e.g., several ms). Thus, there is no need for concern about a drop in the active clamping capacity.

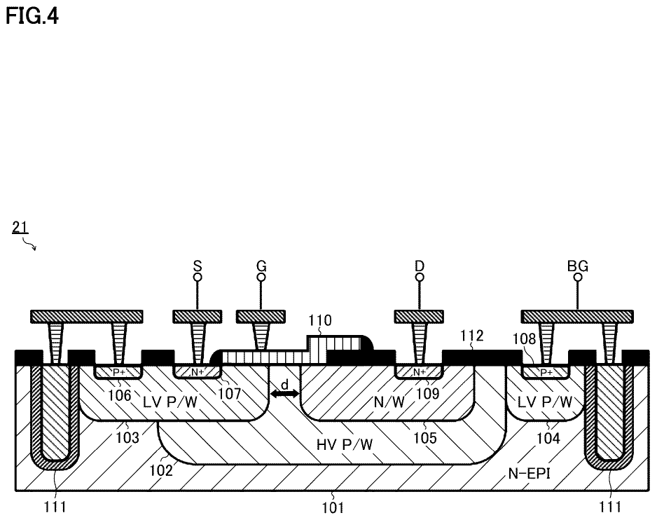

FIG. 4 is a diagram showing the vertical structure of the transistor 21. The transistor 21 of the structure example is formed in an n-type epi layer 101 (i.e., epitaxial growth layer). The n-type epi layer 101 has formed in it a high withstand voltage p-type well 102 and low withstand voltage p-type wells 103 and 104. The low withstand voltage p-type wells 103 and 104 are formed so as to surround the high withstand voltage p-type well 102. The low withstand voltage p-type wells 103 and 104 are formed in regions shallower than that for the high withstand voltage p-type well 102. The low withstand voltage p-type well 103 is formed such that part of it partly covers the surface of the high withstand voltage p-type well 102. The high withstand voltage p-type well 102 has formed in it an n-type well 105. The n-type well 105 is formed to be about as deep as each of the low withstand voltage p-type wells 103 and 104.

The low withstand voltage p-type well 103 has formed in it a high concentration p-type region 106 and a high concentration n-type region 107. A part or all of the high concentration p-type region 106 is exposed on the main surface as the back gate BG of the transistor 21. A part or all of the high concentration n-type region 107 is exposed on the main surface as the source S of the transistor 21. The low withstand voltage p-type well 104 has formed in it a high concentration p-type region 108. A part or all of the high concentration p-type region 108 is exposed on the main surface as the back gate BG of the transistor 21. The n-type well 105 has formed in it a high concentration n-type region 109. A part or all of the high concentration n-type region 109 is exposed on the main surface as the drain D of the transistor 21. On the surfaces of the high withstand voltage p-type well 102, the low withstand voltage p-type well 103, and the n-type well 105, a gate insulating layer 110 is formed so as to extend across those wells. The gate insulating layer 110 electrically conducts to a conductive layer (metal layer) forming the gate G of the transistor 21.

The transistor 21 is formed in a region surrounded by a device separation region 111. The n-type epi layer 101, the high withstand voltage p-type well 102, the low withstand voltage p-type wells 103 and 104, the n-type well 105, the high concentration p-type region 106, the high concentration n-type region 107, the high concentration p-type region 108, the high concentration n-type region 109, the gate insulating layer 110, and the device separation region 111 are, each partly or wholly, covered by a protective layer 112.

Incidentally, when the semiconductor device 1 is incorporated in an industrial machine or a large-sized vehicle such as a truck, the power source voltage VB can be high (e.g., VB can be 24 V, rather than 12 V). This necessitates the clamp voltage Vclp being set so high as not to erroneously activate the active clamp circuit 20 in normal condition. For example, if a battery of 24 V is incorporated, the clamp voltage Vclp needs to be set to around 70 V at the maximum. Thus, the semiconductor device 1 (in particular, the active clamp circuit 20) needs to have a higher withstand voltage.

In general, the withstand voltage of the active clamp circuit 20 can be increased by increasing the number of series diodes 22 or increasing the drain-source withstand voltage of the transistor 21. Increasing the drain-source withstand voltage of the transistor 21 requires a large distance d between the low withstand voltage p-type well 103 and the n-type well 105. That is, the higher the drain-source withstand voltage of the transistor 21, the larger the device size of the transistor 21. This inevitably sets an upper limit over which the drain-source withstand voltage of the transistor 21 cannot be increased. For example, in the semiconductor device 1 of the first embodiment, due to constraints on the circuit area (hence of the chip area), the drain-source withstand voltage of the transistor 21 cannot be raised over approximately 60 V.

Thus, for example, when the clamp voltage Vclp is set to approximately 70 V at the maximum, a method different from those mentioned above is needed to increase the withstand voltage of the active clamp circuit 20.

In view of the considerations above, a new embodiment is presented below that can increase the withstand voltage of the active clamp circuit 20 while suppressing an increase in device size.

### Second Embodiment

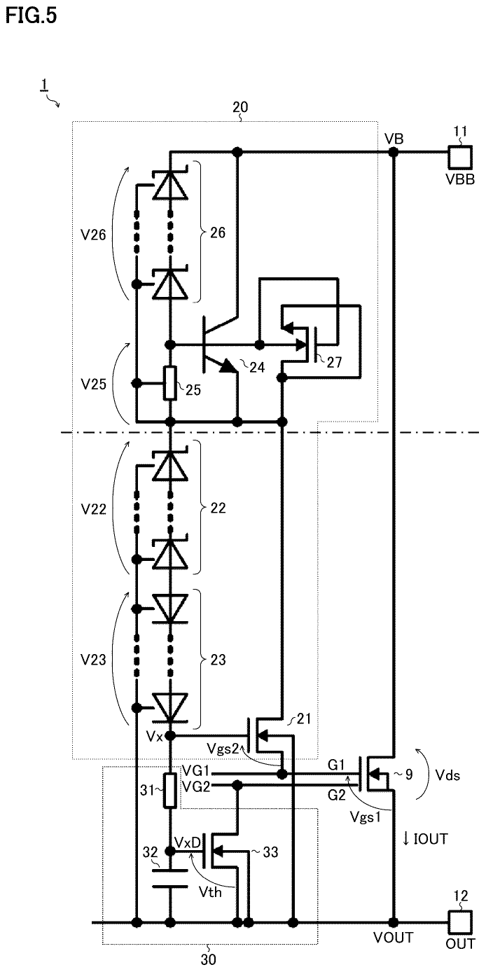

FIG. 5 is a diagram showing a semiconductor device 1 of a second embodiment. The semiconductor device 1 of this embodiment is based on the first embodiment (FIG. 2) described previously but further includes, as circuit elements of the active clamp circuit 20, a parasitic transistor 24, a resistor 25, an x-stage series diode 26, and a dummy transistor 27.

Note that, while, as the circuit elements of the gate disabling circuit 30, only t resistor 31, the capacitor 32, and the transistor 33 are shown, as in the first embodiment (FIG. 2) described previously, the gate disabling circuit 30 can include the transistor 34 and the resistor 35.

Of the additional circuit elements of the active clamp circuit 20, the diode 26 can be a Zener diode; the dummy transistor 27 can be an N-channel MOSFET; and the parasitic transistor 24 can be an npn-type bipolar transistor accompanying the dummy transistor 27.

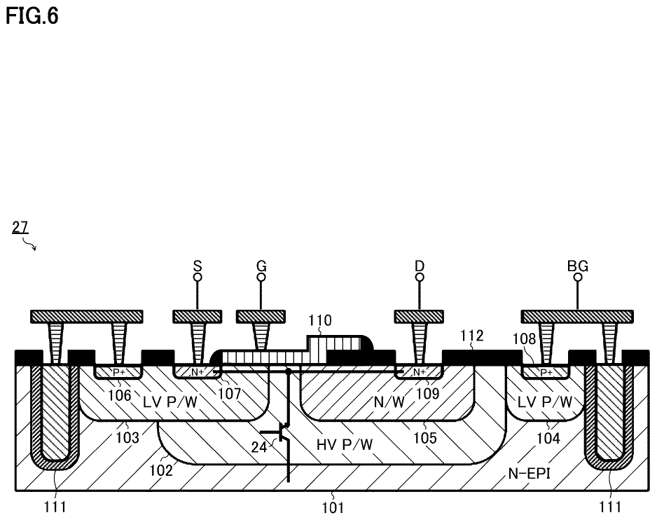

FIG. 6 is a diagram showing the vertical structure of the dummy transistor 27. Note that the vertical structure of the dummy transistor 27 has the same vertical structure as the transistor 21 previously described. Thus, for any parts of the structure already described, the same reference signs are used as in FIG. 4 previously referred to and no overlapping description will be repeated.

As shown in the diagram, the parasitic transistor 24 uses as its collector the n-type epi layer 101 (i.e., the drain of the output transistor 9) in which the dummy transistor 27 is formed. The parasitic transistor 24 uses as its emitter the n-type well 105 and the high concentration n-type regions 107 and 109 (i.e., the source and the drain of the dummy transistor 27). The parasitic transistor 24 uses as its base the high withstand voltage p-type well 102, the low withstand voltage p-type wells 103 and 104, and the high concentration p-type regions 106 and 108 (i.e., the back gate of the dummy transistor 27).

With reference back to FIG. 5, the description of the active clamp circuit 20 continues. The first terminal of the resistor 25 is connected to the base of the parasitic transistor 24 (i.e., the back gate of the dummy transistor 27). The second terminal of the resistor 25 is connected to the emitter of the parasitic transistor 24 (i.e., the source and the drain of the dummy transistor 27). The cathode of the diode 26 is connected to the drain of the output transistor 9 (hence to the external electrode 11). The anode of the diode 26 is connected to the base of the parasitic transistor 24 (i.e., the back gate of the dummy transistor 27).

In the dummy transistor 27, the drain and the source are short-circuited together and the gate and the back gate are short-circuited together. In this way, the dummy transistor 27 is formed not as a device that operates on its own but as a host device accompanied by the parasitic transistor 24.

Adding the circuit elements 24 to 27 requires a slight change in the connection relationship among the circuit elements 21 to 23. In terms of what is shown in the diagram, the drain of the transistor 21 and the cathode of the diode 22 are both connected not to the drain of the output transistor 9 but to the emitter of the parasitic transistor 24 (i.e., the source and the drain of the dummy transistor 27).

Note that the gate-source voltage Vgs1 between the gate G1 and the source of output transistor 9 can be 1.75 V. The gate-source voltage Vgs2 of the transistor 21 can be 2.0 V.

In the m-stage series diode 22, m can be three. In that case, the breakdown voltage V22 (=mVZ) of the diode 22 can be 16.6 V. In the n-stage series diode 23, n can be four. In that case, the forward drop voltage V23 (=nVF) of the diode 23 can be 3.2 V.

In the x-stage series diode 26, x can be seven. In that case, the breakdown voltage V26 (=xVZ) of the diode 26 can be 38.2 V. The voltage V25 across the resistor 25 (i.e., the base-emitter voltage Vbe of the parasitic transistor 24) can be 0.75 V.

Summering up what has been discussed above, in the semiconductor device 1 o this embodiment, the clamp voltage Vclp of the active clamp circuit 20 can be set to 62.5 V (=V26+V25+V22+V23+Vgs2+Vgs1). Here, the voltage applied between the drain and the source of the transistor 21 is limited to 21.8 V (=V22+V23+Vgs2). The voltage applied between the collector and the emitter of the parasitic transistor 24 is limited to 38.95 V (=V26+V25). Accordingly, the transistor 21 and the dummy transistor 27 need not be elements with a super high withstand voltage that can withstand the clamp voltage Vclp.

For example, usable as the transistor 21 and the dummy transistor 27 are elements with a withstand voltage of 55 V. In addition, the diodes 22, 23, and 26 can be designed to have cathode-well withstand voltages comparable with those before (e.g., a withstand voltage of 55 V) suffice. Thus, there is no need to change the production process for the semiconductor device 1.

With this two-stage clamp structure using the parasitic transistor 24, it is possible to increase the withstand voltage of the active clamp circuit 20 without an increase in the device sizes of the transistor 21 and the dummy transistor 27.

Note that the number (x) of series stages in the diode 26 can be more than the number (m) of series stages in the diode 22. This configuration helps suppress the current that flows into the diodes 22 and 23 in the lower stage, for example, when the parasitic transistor 24 is turned on.

### Third Embodiment

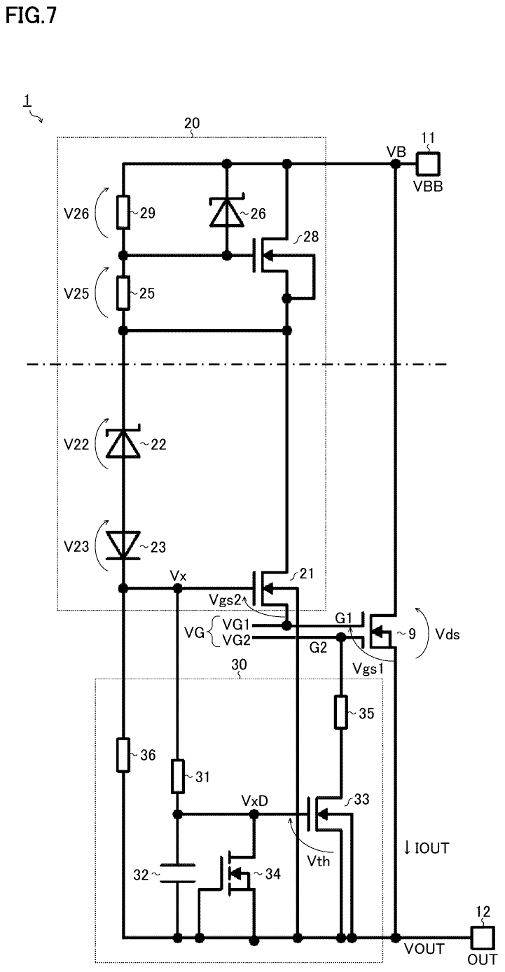

FIG. 7 is a diagram showing a semiconductor device 1 of a third embodiment. The semiconductor device 1 of this embodiment is based on the second embodiment (FIG. 5) previously described but has a modified active clamp circuit 20 and a modified gate disabling circuit 30. In terms of what is shown in the diagram, the active clamp circuit 20 includes, instead of the parasitic transistor 24 and the dummy transistor 27 previously described, a transistor 28 and a resistor 29. The transistor 28 can be an N-channel MOSFET. Usable as the transistor 28 is an element with a withstand voltage of 55 V. In addition, the gate disabling circuit 30 further includes a resistor 36.

The cathode of the diode 26, the drain of the transistor 28, and the first terminal of the resistor 29 are all connected to the drain of the output transistor 9 (hence to the external electrode 11). The first terminal of the resistor 25, the anode of the diode 26, and the second terminal of the resistor 29 are all connected to the gate of the transistor 28. The cathode of the diode 22, the second terminal of the resistor 25, and the source and the back gate of the transistor 28 are all connected to the drain of the transistor 21. The resistor 36 is connected between the application terminal for the internal node voltage Vx (i.e., the gate of the transistor 21) and an application terminal for the output voltage VOUT (i.e., the external electrode 12).

In the m-stage series diode 22, m can be nine. In the n-stage series diode 23, can be four. The diode 26 can include four diodes in parallel in order to suppress the peak of the breakdown voltage V26 with the gate G2 is disabled.

The semiconductor device 1 of this embodiment, like that of the second embodiment (FIG. 5) previously described, has an active clamp circuit 20 with a two-stage clamp structure. Thus, it is possible to increase the withstand voltage of the active clamp circuit 20 without increasing the device sizes of the transistors 21 and 28.

### Modified Example

The above embodiments deal with an output transistor 9 of a split-gate type as an example. The output transistor 9 can instead be of a single gate type, that is, one with the gate G1 alone. In that case, the gate disabling circuit 30 can be omitted.

In addition, the output transistor 9 can function as a low-side switch that electrically connects and disconnects the load and the ground terminal. In that case, the external electrode 11 is the output electrode (i.e., the load connection electrode); and the external electrode 12 is the reference voltage electrode (i.e., the ground electrode).

### Application to Vehicle

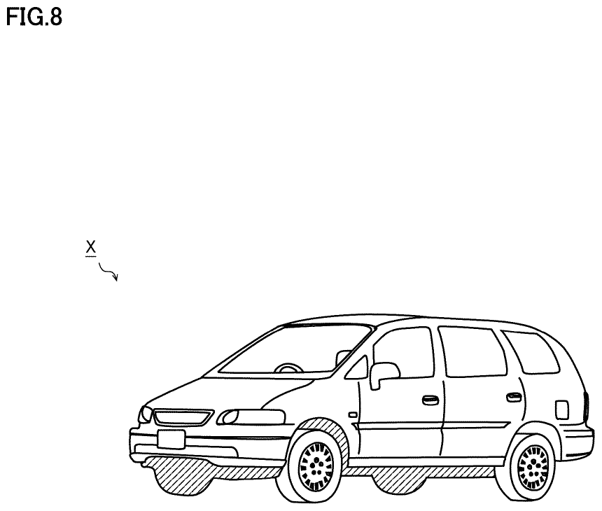

FIG. 8 is a diagram showing the exterior appearance of a vehicle X. The vehicle X of this configuration example incorporates various electronic devices that operate with power supplied from a battery.

The vehicle X can be an engine vehicle, or an electric vehicle (an xEV such as a BEV [battery electric vehicle], an HEV [hybrid electric vehicle], a PHEV/PHV [plug-in hybrid electric vehicle/plug-in hybrid vehicle], or an FCEV/FCV [fuel cell electric vehicle/fuel cell vehicle]).

The semiconductor device 1 described previously can be built in any of the electronic devices incorporated in the vehicle X.

### Overview

To follow is an overview of the above disclosure. Based on the disclosure, it i possible to increase the withstand voltage of an active clamp circuit.

### Note 1

An active clamp circuit (20) includes a first transistor (21) having its first main electrode connected to the control electrode of an output transistor (9), a first diode (22) and a second diode (23) serially connected with opposite polarities between the control electrode and the second main electrode of the first transistor (21), a second transistor (24) having its first main electrode connected to the second main electrode of the first transistor (21) and having its second main electrode connected to the first main electrode of the output transistor (9), a first resistor (25) connected between the control electrode and the first main electrode of the second transistor (24), and a third diode (26) connected between the control electrode and the second main electrode of the second transistor (24).

### Overview 2

In the active clamp circuit according to note 1, the first diode (22) and the third diode (26) can be Zener diodes, and the second diode (23) can be a polysilicon diode.

### Note 3

The active clamp circuit (20) according to note 1 or 2 can further include a third transistor (27) having its drain and its source connected to the second main electrode of the first transistor (21) and having its gate and its back gate short-circuited together. In the active clamp circuit (20) according to note 1 or 2, the second transistor (24) can be a parasitic transistor accompanying the third transistor (27).

### Note 4

The active clamp circuit according to note 1 or 2 can further include a second resistor (29) connected between the control electrode and the second main electrode of the second transistor (24).

### Note 5

A semiconductor device (1) includes the active clamp circuit (20) according to any one of notes 1 to 4, the output transistor (9), a first external electrode (11) to which the first main electrode of the output transistor (9) is connected, and a second external electrode (12) to which the second main electrode of the output transistor is connected.

### Note 6

In the semiconductor device (1) according to note 5, the first external electrode (11) can be a power source electrode, the second external electrode (12) can be an output electrode, and the output transistor (9) can function as a high-side switch.

### Note 7

In the semiconductor device (1) according to note 5, the first external electrode (11) can be an output electrode, the second external electrode (12) can be a reference voltage electrode, and the output transistor (9) can function as a low-side switch.

### Note 8

In the semiconductor device (1) according to any one of notes 5 to 7, the output transistor (9) can have a first control electrode (G1) for individually controlling a first channel region and a second control electrode (G2) for individually controlling a second channel region, and the active clamp circuit (20) can drive the first control electrode (G1) with the second control electrode (G2) disabled.

### Note 9

An electronic device (A) includes the semiconductor device (1) according to any one of notes 5 to 8 and a load (3) connected to the semiconductor device.

### Note 10

A vehicle (X) includes the electronic device (A) according to note 9.

### Endnotes

The various technical features disclosed in the present description can be implemented in any manner other than as specifically described above and allow for various modifications without departure from the spirit of their technical ingenuity. That is, the embodiments described above should be taken to be in every aspect illustrative and not restrictive. The technical scope of the present disclosure should be understood to be defined by the appended claims and to encompass any variations within a scope equivalent in significance to the scope of those claims.

1. An active clamp circuit comprising:
a first transistor having a first main electrode thereof connected to a control electrode of an output transistor;
a first diode and a second diode serially connected with opposite polarities between a control electrode and a second main electrode of the first transistor;
a second transistor having a first main electrode thereof connected to the second main electrode of the first transistor and having a second main electrode thereof connected to a first main electrode of the output transistor;
a first resistor connected between a control electrode and the first main electrode of the second transistor; and
a third diode connected between the control electrode and the second main electrode of the second transistor.

2. The active clamp circuit according to claim 1, wherein
the first and third diodes are Zener diodes, and
the second diode is a polysilicon diode.

3. The active clamp circuit according to claim 1 further comprising:
a third transistor having a drain and a source thereof connected to the second main electrode of the first transistor and having a gate and a back gate thereof short-circuited together,
wherein
the second transistor is a parasitic transistor accompanying the third transistor.

4. The active clamp circuit according to claim 1 further comprising:
a second resistor connected between the control electrode and the second main electrode of the second transistor.

5. A semiconductor device comprising:
the active clamp circuit according to claim 1;
the output transistor;
a first external electrode to which the first main electrode of the output transistor is connected; and
a second external electrode to which a second main electrode of the output transistor is connected.

6. The semiconductor device according to claim 5, wherein
the first external electrode is a power source electrode,
the second external electrode is an output electrode, and
the output transistor functions as a high-side switch.

7. The semiconductor device according to claim 5, wherein
the first external electrode is an output electrode,
the second external electrode is a reference voltage electrode, and
the output transistor functions as a low-side switch.

8. The semiconductor device according to claim 1, wherein
the output transistor has a first control electrode for individually controlling a first channel region and a second control electrode for individually controlling a second channel region, and
the active clamp circuit drives the first control electrode with the second control electrode disabled.

9. An electronic device comprising:
the semiconductor device according to claim 5; and
a load connected to the semiconductor device.

10. A vehicle comprising:
the electronic device according to claim 9.
